(19) United States
(12) Patent Application Publication
(10) Pub. No.: US 2025/0006788 A1
(43) Pub. Date: Jan. 2, 2025

(54) NANOSHEET HEIGHT CONTROL WITH DENSE OXIDE SHALLOW TRENCH ISOLATION

(71) Applicant: International Business Machines Corporation, Armonk, NY (US)

(72) Inventors: Min Gyu Sung, Latham, NY (US); Rishikesh Krishnan, Cohoes, NY (US); Erin Stuckert, Albany, NY (US); Nicolas Jean Loubet, GUILDERLAND, NY (US); Julien Frougier, Albany, NY (US)

(21) Appl. No.: 18/342,821

(22) Filed: Jun. 28, 2023

(51) Int. Cl. H01L 29/06; H01L 21/762; H01L 21/768; H01L 21/8238; H01L 27/092; H01L 29/423; H01L 29/66; H01L 29/775; H01L 29/786

(52) U.S. Cl. CPC H01L 29/0673; H01L 21/76229; H01L 21/76843; H01L 21/823807; H01L 21/823878; H01L 27/092; H01L 29/42392; H01L 29/66439; H01L 29/775; H01L 29/78696

(57) ABSTRACT

A semiconductor device includes a plurality of first nanosheet fin structures located in a dense array region of a substrate. The semiconductor device further includes a plurality of first isolation trenches between adjacent first nanosheet fin structures of the plurality of first nanosheet fin structures. The plurality of first isolation trenches include: a first trench isolation layer, a protective liner formed on top of the first trench isolation layer, and a second trench isolation layer located above the protective liner. The protective liner separates the first trench isolation layer from the second trench isolation layer and the first trench isolation layer is more dense than the second trench isolation layer.

### BACKGROUND

The present disclosure generally relates to fabrication methods and structures for semiconductor devices, and more specifically, to techniques for forming nanosheet devices having multiple device regions separated by a shallow trench isolation (STI) area.

As integrated circuits (ICs) continue to move to smaller technology nodes, the ability to meet transistor performance demands with smaller dimensions (i.e., larger drive currents for a given footprint) becomes increasingly challenging, especially when forming nanosheet transistor devices having multiple device regions separated by a shallow trench isolation (STI) area. One particular challenge is the ability to maintain a uniform nanosheet height between the nanosheet transistor devices formed in the different device regions, both during and post nanosheet processing.

### SUMMARY

According to one embodiment of the present invention, a semiconductor device having improved nanosheet height control is provided. The semiconductor device includes a plurality of first nanosheet fin structures located in a dense array region of a substrate. The semiconductor device further includes a plurality of first isolation trenches between adjacent first nanosheet fin structures of the plurality of first nanosheet fin structures. The plurality of first isolation trenches include a first trench isolation layer, a protective layer formed on top of the first trench isolation layer, and a second trench isolation layer located above the protective liner. The first trench isolation layer is more dense than the second trench isolation layer. The protective liner separates the first trench isolation layer from the second trench isolation layer.

According to another aspect of the present invention, a semiconductor device having improved nanosheet height control is provided. The semiconductor device includes a plurality of first nanosheet fin structures located in a dense array region of a substrate. The semiconductor device further includes a plurality of first isolation trenches between adjacent first nanosheet fin structures of the plurality of first nanosheet fin structures. The plurality of first isolation trenches include a first trench isolation layer, a protective layer formed on top of the first trench isolation layer, and a second trench isolation layer located above the protective liner. The second trench isolation layer is more dense than the first trench isolation layer. The protective liner separates the first trench isolation layer from the second trench isolation layer.

According to another embodiment of the present invention, a method of forming a semiconductor device is provided. The method includes arranging a nanosheet stack on top of a substrate. The method further includes patterning the nanosheet stack and the substrate to form a plurality of first nanosheet fin structures in a dense array region of the substrate and at least one second nanosheet fin structure in an isolated region of the substrate. Patterning the nanosheet stack and the substrate further results in the formation of a plurality of first isolation trenches between adjacent first nanosheet fin structures of the plurality of nanosheet fin structures, and a second isolation trench separating the plurality of first fin structures in the dense array region of the substrate from the at least one second nanosheet fin in the isolated region of the substrate. The plurality of first isolation trenches are narrower than the second isolation trench.

The method further includes simultaneously depositing a first oxide material within the plurality of first isolation trenches and the second isolation trench to form a first trench isolation layer. The deposition rate is higher in the second isolation trench than in the plurality of first isolation trenches due to a deposition-loading effect. The method further includes stopping simultaneously depositing the first oxide in the plurality of first isolation trenches and the second isolation trench when a first height of the first trench isolation layer in the second isolation trench is substantially coplanar with a bottom surface of a nanosheet portion of the at least one second nanosheet fin structure, at which point a second height of the first trench isolation layer in the plurality of first isolation trenches is below the bottom surface of the nanosheet portion of the plurality of first nanosheet fin structures. The method further includes conformally depositing a protective liner material to form a protective liner over the first trench isolation layer, the plurality of first nanosheet fin structures in the dense array region, and the at least one second nanosheet fin structure in the isolated region. The method further includes simultaneously depositing a second oxide material within the plurality of first isolation trenches and the second isolation trench to form a second trench isolation layer. The second trench isolation layer is less dense than the first trench isolation layer. The method further includes simultaneously performing a dry etching process in the dense array region and the isolated region that is selective to the second trench isolation layer over the protective liner. The etch rate of the second trench isolation layer is faster in the isolated region than in the dense array region due to a dry etch-loading effect. The method further includes stopping simultaneously performing the dry etching process in the dense array region and the isolated region when a third height of the second trench isolation layer in the dense array region is substantially coplanar with the bottom surface of the nanosheet stack portion of the plurality of first nanosheet fin structures, at which point all of the second trench isolation layer has been removed from the isolated region.

According to another embodiment of the present invention, a method of forming a semiconductor device is provided. The method includes arranging a nanosheet stack on top of a substrate. The method further includes patterning the nanosheet stack and the substrate to form a plurality of first nanosheet fin structures in a dense array region of the substrate and at least one second nanosheet fin structure in an isolated region of the substrate. Patterning the nanosheet stack and the substrate further results in the formation of a plurality of first isolation trenches between adjacent first nanosheet fin structures of the plurality of nanosheet fin structures, and a second isolation trench separating the plurality of first nanosheet fin structures in the dense array region of the substrate from the at least one second nanosheet fin structure in the isolated region of the substrate. The plurality of first isolation trenches are narrower than the second isolation trench.

The method further includes conformally depositing a protective liner material to form a first protective liner over the plurality of first nanosheet fin structures in the dense array region of the substrate and the at least one second nanosheet fin structure in the isolated region of the substrate. The method further includes simultaneously depositing a first oxide material within the plurality of first isolation trenches and the second isolation trench to form a first trench isolation layer. The method further includes simultaneously performing one or more etching processes in the dense array region and the isolated region to recess the first trench isolation layer below a bottom surface of a nanosheet portion of the plurality of first nanosheet fin structures and the at least one second nanosheet fin structure. The method further includes depositing the protective liner material to form a second protective liner over the first trench isolation layer. The method further includes simultaneously depositing a second oxide material within the plurality of first isolation trenches and the second isolation trench to form a second trench isolation layer. The second trench isolation layer is denser than the first trench isolation layer. The method further includes simultaneously performing an etching process in the dense array region and the isolated region to recess the second trench isolation layer until the second trench isolation layer is substantially coplanar with the bottom surface of the nanosheet stack portion of the plurality of first nanosheet fin structures and the at least one second nanosheet fin structure.

### BRIEF DESCRIPTION OF THE SEVERAL VIEWS OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a cross-sectional view of an initial semiconductor interconnect structure, generally designated 100, in accordance with at least one embodiment of the present invention.

FIG. 2 illustrates a cross-sectional view of semiconductor structure 100 after performing subsequent processing steps, generally designated 200, in accordance with at least one embodiment of the present invention.

FIG. 3 illustrates a cross-sectional view of semiconductor structure 200 after performing subsequent processing steps, generally designated 300, in accordance with at least one embodiment of the present invention.

FIG. 4 illustrates a cross-sectional view of semiconductor structure 300 after performing subsequent processing steps, generally designated 400, in accordance with at least one embodiment of the present invention.

FIG. 5A illustrates a cross-sectional view of semiconductor structure 400 after performing subsequent processing steps, generally designated 500A, in accordance with at least one embodiment of the present invention.

FIG. 6A illustrates a cross-sectional view of semiconductor structure 500A after performing subsequent processing steps, generally designated 600A, in accordance with at least one embodiment of the present invention.

FIG. 7A illustrates a cross-sectional view of semiconductor structure 600A after performing subsequent processing steps, generally designated 700A, in accordance with at least one embodiment of the present invention.

FIG. 8A illustrates a cross-sectional view of semiconductor structure 700A after performing subsequent processing steps, generally designated 800A, in accordance with at least one embodiment of the present invention.

FIG. 5B illustrates a cross-sectional view of semiconductor structure 400 after performing subsequent processing steps, generally designated 500B, in accordance with at least one embodiment of the present invention.

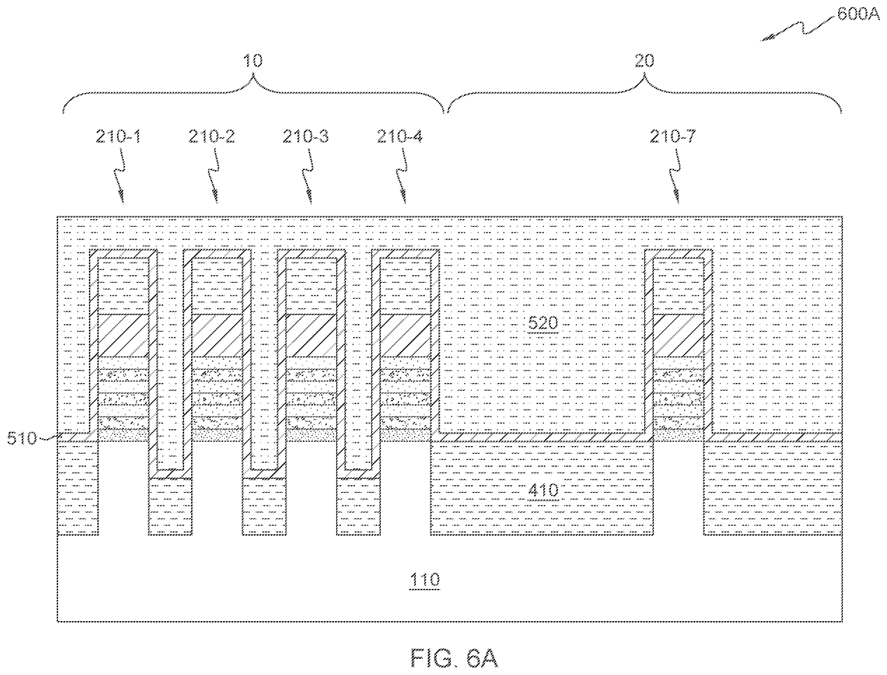

FIG. 6B illustrates a cross-sectional view of semiconductor structure 500B after performing subsequent processing steps, generally designated 600B, in accordance with at least one embodiment of the present invention.

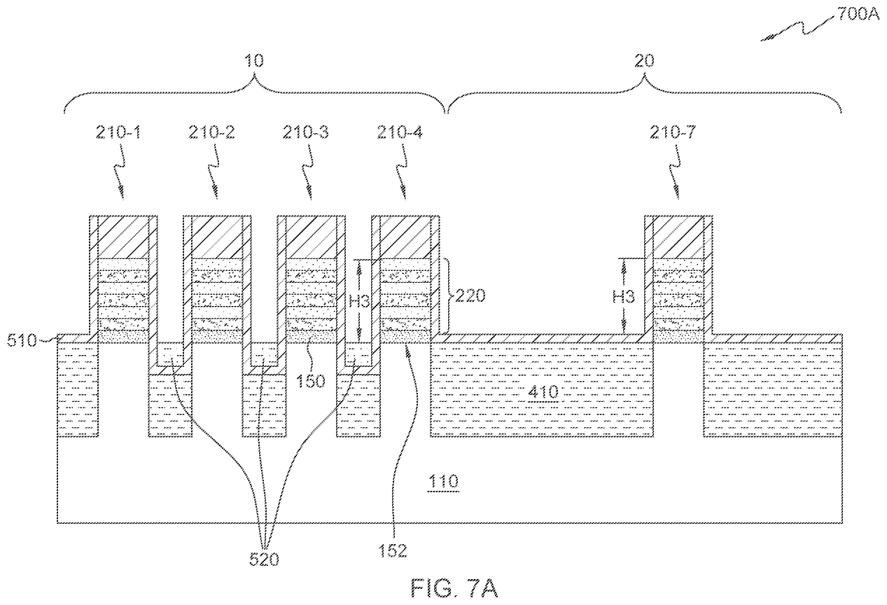

FIG. 7B illustrates a cross-sectional view of semiconductor structure 600B after performing subsequent processing steps, generally designated 700B, in accordance with at least one embodiment of the present invention.

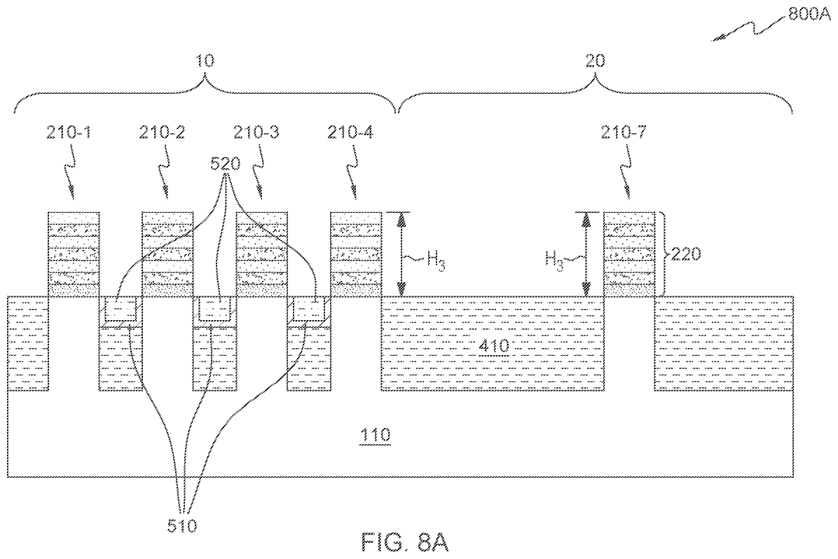

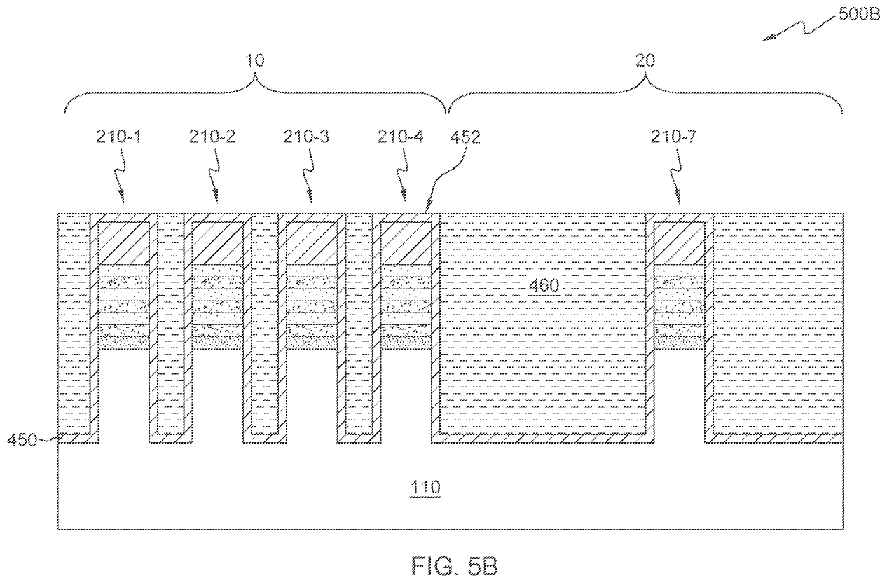

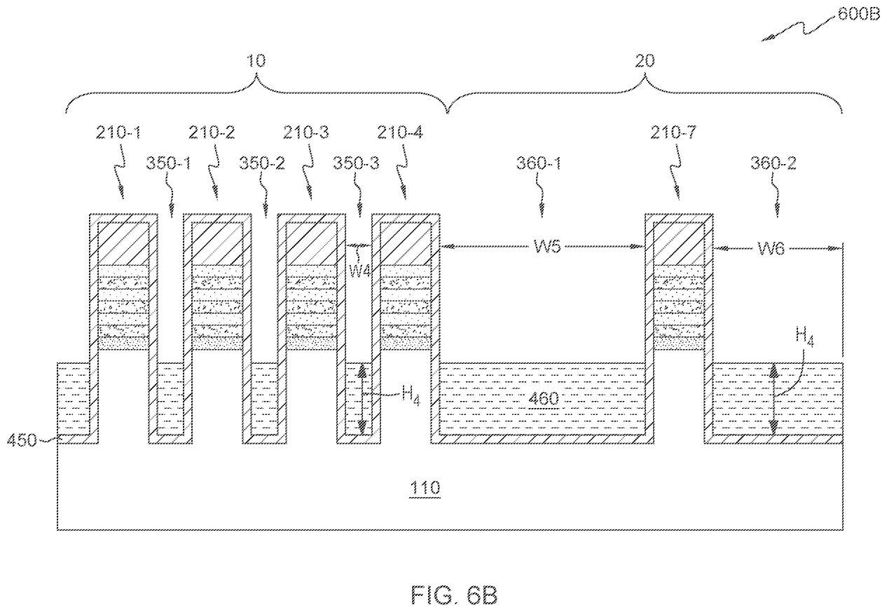

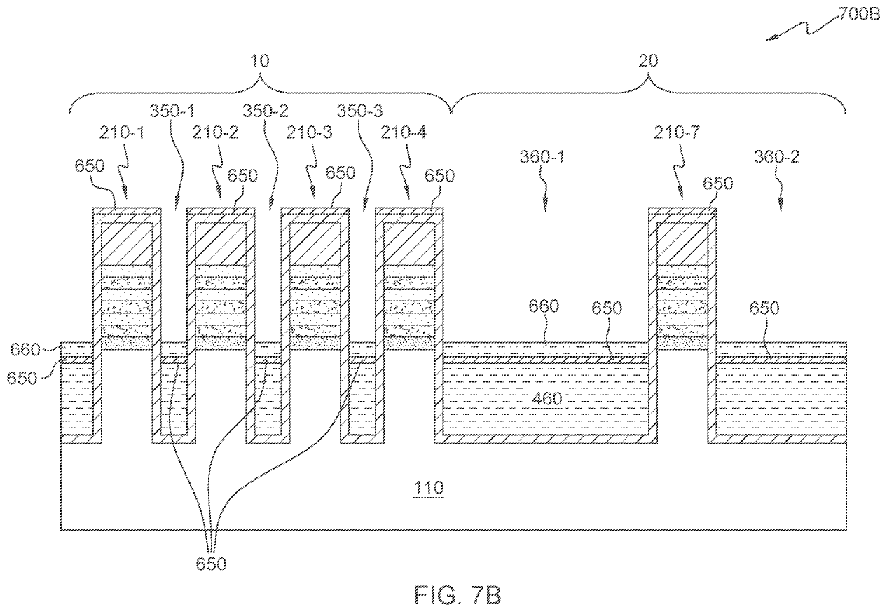

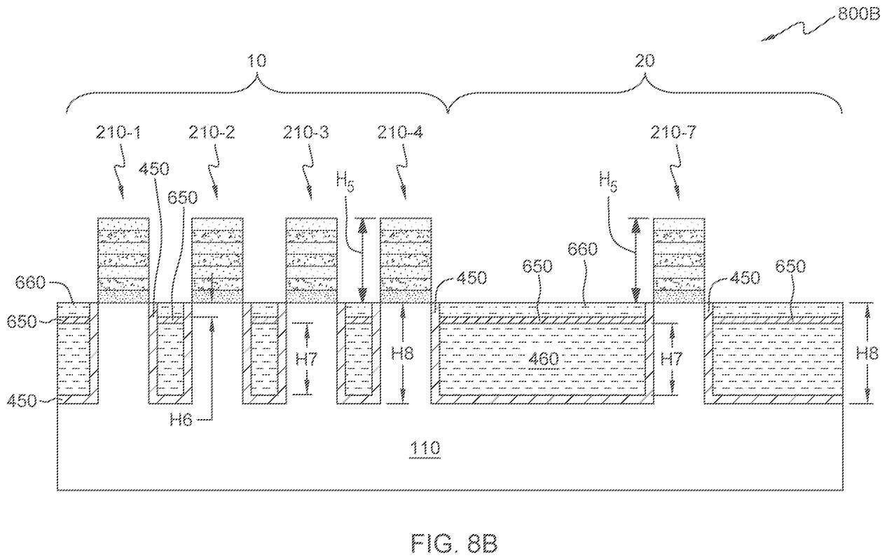

FIG. 8B illustrates a cross-sectional view of semiconductor structure 700B after performing subsequent processing steps, generally designated 800B, in accordance with at least one embodiment of the present invention.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the disclosure.

### DETAILED DESCRIPTION

Embodiments of the present invention recognize that when forming semiconductor devices having multiple active nanosheet device regions (i.e., nanosheet devices formed on a substrate including a dense array region and an isolated region), there are various reasons that can contribute to active height (i.e., reveal height) variations between the nanosheet devices of the dense array and isolated regions. One possible reason for the nanosheet active height variation is during nanosheet processing, in which differences in the trench width between the shallow trench isolation (STI) regions in the dense array region and the isolated region can affect the recess rate of an STI oxide, such as silicon dioxide (SiO2), formed within the respective STI regions. In order to circumvent this problem, a multistep nanosheet reveal process may be used when different trench widths exist. For example, a wet etching process may be followed by a dry etching process (or vice versa) since the etch rate using the wet etching process alone will be higher in the dense array region than the isolated region, while the etch rate using the dry etching process alone will be higher in the isolated region than the dense array region. However, it is difficult to control the nanosheet height using this multistep process, which often results in variations in nanosheet height between the dense array and isolated regions.

Another possible reason for the nanosheet active height variation is due to the quality of the STI oxide (e.g., SiO₂) used in the STI regions in the dense array and isolated regions. Current practices typically form an STI layer by performing flowable chemical vapor deposition (FCVD) of silicon dioxide (SiO₂) (also known as “flowable oxide”). However, although FCVD of silicon dioxide is often used for its gap fill capabilities in the narrower, STI regions of the dense array region, it also results in a less dense/poorer quality oxide. The less dense STI oxide (e.g., SiO₂) may be vulnerable to an increased recess rate during pre-nanosheet processes, such as pre epitaxial cleaning of the silicon substrate (e.g., using a buffered oxide etch (BOE)) for subsequent nanosheet formation, as well as during post nanosheet processes, such as gate spacer and P-N junction formation, both of which can result in gate flop-over caused by undercutting of the STI silicon dioxide under the gate, especially in the isolated region.

Embodiments of the present invention provide for nanosheet devices formed in multiple device regions (i.e., dense array and isolated regions) that have improved active nanosheet height control during nanosheet processing, as well as during pre-nanosheet and post-nanosheet processes. According to one aspect of the present invention, a method of forming a semiconductor device having improved nanosheet height control is provided. The method includes arranging a nanosheet stack on top of a substrate. The method further includes patterning the nanosheet stack and the substrate to form a plurality of first nanosheet fin structures in a dense array region of the substrate and at least one second nanosheet fin structure in an isolated region of the substrate. Patterning the nanosheet stack and the substrate further results in the formation of a plurality of first isolation trenches between adjacent first nanosheet fin structures of the plurality of nanosheet fin structures, and a second isolation trench separating the plurality of first nanosheet fin structures in the dense array region of the substrate from the at least one second nanosheet fin structure in the isolated region of the substrate. The plurality of first isolation trenches are narrower than the second isolation trench.

The method further includes simultaneously depositing a first oxide material within the plurality of first isolation trenches and the second isolation trench to form a first trench isolation layer. The deposition rate is higher in the second isolation trench than in the plurality of first isolation trenches due to a deposition-loading effect. This results in a technical effect of the plurality of first isolation trenches being filled with the first oxide material faster than the second isolation trench. The method further includes stopping simultaneously depositing the first oxide within the plurality of first isolation trenches and the second isolation trench when a first height of the first trench isolation layer in the second isolation trench is substantially coplanar with a bottom surface of a nanosheet portion of the at least one second nanosheet fin structure, at which point a second height of the first trench isolation layer in the plurality of first isolation trenches is below the bottom surface of the nanosheet portion of the plurality of first nanosheet fin structures due to the deposition-loading effect. This results in a technical effect of the height of the first trench isolation layer in the second isolation trench being higher than the height of first trench isolation layer in the plurality of first isolation trenches. This also results in a technical advantage of the final nanosheet height of the second nanosheet fin structure in the isolated region being completed during the deposition of the first oxide material, without the need for any etching processes. This also results in a technical advantage of being able to target the deposition of the first oxide material to the isolated region in order to obtain the final nanosheet height of the second nanosheet fin structure.

The method further includes conformally depositing a protective liner material to form a protective liner over the first trench isolation layer, the plurality of first nanosheet fin structures in the dense array region, and the at least one second nanosheet fin structure in the isolated region. The protective liner results in a technical effect of preventing oxidation of the patterned nanoshect stack during any subsequent annealing processes for densification of the less dense, second trench isolation layer. The method further includes simultaneously depositing a second oxide material within the plurality of first isolation trenches and the second isolation trench to form a second trench isolation layer. The second trench isolation layer is less dense than the first trench isolation layer. The more dense, first trench isolation layer located in the second isolation trench of the isolated region has the technical effect of being less vulnerable to etching during pre-nanosheet processes, such as pre epitaxial cleaning of the silicon substrate (e.g., using a buffered oxide etch (BOE)) for subsequent nanosheet formation, which ultimately reduces the potential for gate flop-over caused by undercutting the oxide under the gate, especially in the isolated region. The more dense, first trench isolation layer located in the second isolation trench of the isolated region also has the technical effect of being less vulnerable to etching during post-nanosheet processes, such as gate spacer and P-N junction formation, which ultimately reduces the potential for gate flop-over caused by undercutting of the oxide under the gate, especially in the isolated region.

The method further includes simultaneously performing a dry etching process in the dense array region and the isolated region that is selective to the second trench isolation layer over the protective liner. The etch rate of the second trench isolation layer is faster in the isolated region than in the dense array region due to a dry etch-loading effect. This results in a technical effect of the second trench isolation layer being removed faster from the isolated region than from the dense array region. The use of a dry etching process that is selective to the second trench isolation layer over the protective liner results in the technical advantage of being able to continue to remove the second trench isolation layer from the plurality of first isolation trenches of the dense array region until the nanosheet height of the first nanosheet fin structures in the dense array region equals the nanosheet height of the second nanosheet fin structure in the isolated region, without concern of altering the nanosheet height of the second nanosheet fin structure in the isolated region during the process. In other words, the use of a dry etching process that is selective to the second trench isolation layer over the protective liner results in the technical advantage of being able to target the dry etch process to the dense array region to obtain the final nanosheet height of the plurality of first nanosheet fin structures. The method further includes stopping simultaneously performing the dry etching process in the dense array region and the isolated region when a third height of the second trench isolation layer in the dense array region is substantially coplanar with the bottom surface of the nanosheet stack portion of the plurality of first nanosheet fin structures, at which point all of the second trench isolation layer has been removed from the isolated region.

In an embodiment, a first height of the first trench isolation layer is greater than a second height of the second trench isolation layer.

In an embodiment, the first oxide material used to form the first trench isolation layer and the second oxide material used to form the second trench isolation layer are silicon dioxide.

In an embodiment, simultaneously depositing the first oxide material within the plurality of first isolation trenches and the second isolation trench to form the first trench isolation layer includes performing high density plasma chemical vapor deposition of silicon dioxide, and simultaneously depositing the second oxide material within the plurality of first isolation trenches and the second isolation trench to form the second trench isolation layer includes performing flowable chemical vapor deposition of silicon dioxide. This results in a technical effect of the first trench isolation layer being more dense then the second trench isolation layer.

In an embodiment, simultaneously depositing the first oxide material within the plurality of first isolation trenches and the second isolation trench to form the first trench isolation layer includes performing flowable chemical vapor deposition of silicon dioxide, and simultaneously depositing the second oxide material within the plurality of first isolation trenches and the second isolation trench to form the second trench isolation layer includes performing high density plasma chemical vapor deposition of silicon dioxide. This results in a technical effect of the second trench isolation layer being more dense then the first trench isolation layer.

According to another aspect of the present invention, a method of forming a semiconductor device having improved nanosheet height control is provided. The method includes arranging a nanosheet stack on top of a substrate. The method further includes patterning the nanosheet stack and the substrate to form a plurality of first nanosheet fin structures in a dense array region of the substrate and at least one second nanosheet fin structure in an isolated region of the substrate. Patterning the nanosheet stack and the substrate further results in the formation of a plurality of first isolation trench regions between adjacent first nanosheet fin structures of the plurality of nanosheet fin structures, and a second isolation trench separating the plurality of first nanosheet fin structures in the dense array region of the substrate from the at least one second nanosheet fin structure in the isolated region of the substrate. The plurality of first isolation trenches are narrower than the second isolation trench.

The method further includes conformally depositing a protective liner material to form a first protective liner over the plurality of first nanosheet fin structures in the dense array region of the substrate and the at least one second nanosheet fin structure in the isolated region of the substrate. The method further includes simultaneously depositing a first oxide material within the plurality of first isolation trenches and the second isolation trench to form a first trench isolation layer. The protective liner results in a technical effect of preventing oxidation of the patterned nanosheet stack during any subsequent annealing processes for densification of the first trench isolation layer.

The method further includes simultaneously performing one or more etching processes in the dense array region and the isolated region to recess the first trench isolation layer below a bottom surface of a nanosheet portion of the plurality of first nanosheet fin structures, and the at least one second nanosheet fin structure. This results in a technical effect of providing a uniform height of the first trench isolation layer in the first trench isolation region of the dense array region and the second trench isolation region of the isolated region.

The method further includes depositing the protective liner material to form a second protective liner over the first trench isolation layer. The method further includes simultaneously depositing a second oxide material within the plurality of first isolation trenches and the second isolation trench to form a second trench isolation layer. The second trench isolation layer is denser than the first trench isolation layer. The more dense, second trench isolation layer in the dense array region and isolated region has the technical effect of being less vulnerable to etching during pre-nanosheet processes, such as pre epitaxial cleaning of the silicon substrate (e.g., using a buffered oxide etch (BOE)) for subsequent nanosheet formation, which ultimately reduces the potential for gate flop-over caused by undercutting of the oxide under the gate, especially in the isolated region. The more dense, second trench isolation layer in the dense array region and isolated region also has the technical effect of being less vulnerable to etching during post-nanosheet processes, such as gate spacer and P-N junction formation, which ultimately reduces the potential for gate flop-over caused by undercutting of the oxide under the gate, especially in the isolated region. The method further include simultaneously performing an etching process in the dense array region and the isolated region to recess the second trench isolation layer until the second trench isolation layer is substantially coplanar with the bottom surface of the nanosheet stack portion of the plurality of first nanosheet fin structures and the at least one second nanosheet fin structure. This results in a technical effect of the plurality of first nanosheet fin structures and the second nanosheet fin structure being uniform in height.

In an embodiment, the first trench isolation layer formed in the dense array region has a same first height as the first trench isolation layer formed in the isolated region, and the second trench isolation layer formed in the dense array region has a same second height as the second trench isolation layer formed in the isolated region.

In an embodiment, the first oxide material used to form first trench isolation layer, and the second oxide material used to form the second trench isolation layer are both silicon dioxide.

According to another aspect of the present invention, a semiconductor device having improved nanosheet height control is provided. The semiconductor device includes a plurality of first nanosheet fin structures located in a dense array region of a substrate. The semiconductor device further includes a plurality of first isolation trenches between adjacent first nanosheet fin structures of the plurality of first nanosheet fin structures. The plurality of first isolation trenches include a first trench isolation layer, a protective layer formed on top of the first trench isolation layer, and a second trench isolation layer located above the protective liner. The first trench isolation layer is more dense than the second trench isolation layer. The protective liner separates the first trench isolation layer from the second trench isolation layer. Thus, illustrative embodiments provide for a technical effect of improved active height control during nanosheet processing, as well as during pre-nanosheet and post-nanosheet processes.

In an embodiment, a first height of the first trench isolation layer in the plurality of first isolation trenches is greater than a second height of the second trench isolation layer in the plurality of first isolation trenches.

In an embodiment, the first trench isolation layer is formed from a first oxide and the second trench isolation layer is formed from a second oxide.

In an embodiment, the first oxide used to form the first trench isolation layer and the second oxide used to form the second trench isolation layer are silicon dioxide.

In an embodiment, the first trench isolation layer is formed from high density plasma chemical vapor deposition of silicon dioxide, and the second trench isolation layer is formed from flowable chemical vapor deposition of silicon dioxide. This results in a technical effect of the first trench isolation layer being more dense then the second trench isolation layer.

In an embodiment, the second trench isolation layer in the plurality of first isolation trenches is substantially coplanar with a bottom surface of a nanosheet portion of the plurality of first nanosheet fin structures.

In an embodiment, the protective liner is further formed along respective sidewall portions the plurality of first isolation trenches extending between a top surface of the first trench isolation layer to a bottom surface of a nanosheet portion of the plurality of first nanosheet fin structures. This results in a technical effect of the second trench isolation layer in the dense array region being less vulnerable to etching during pre-nanosheet processes, such as pre epitaxial cleaning of the silicon substrate (e.g., using a buffered oxide etch (BOE)) for subsequent nanosheet formation, which ultimately reduces the potential for gate flop-over caused by undercutting the oxide under the gate. This also results in a technical effect of the second trench isolation layer in the dense array region being less vulnerable to etching during post-nanosheet processes, such as gate spacer and P-N junction formation, which ultimately reduces the potential for gate flop-over caused by undercutting of the oxide under the gate.

In an embodiment, the semiconductor device further includes a second isolation trench separating the plurality of first fin structures in the dense array region of the substrate from at least one second nanosheet fin in an isolated region of the substrate. The plurality of first isolation trenches are narrower than the second isolation trench. The second isolation trench includes the first isolation layer. The more dense, first trench isolation layer in the second isolation trench has a technical effect of being less vulnerable to etching during pre-nanosheet processes, such as pre epitaxial cleaning of the silicon substrate (e.g., using a buffered oxide etch (BOE)) for subsequent nanosheet formation, which ultimately reduces the potential for gate flop-over caused by undercutting of the oxide under the gate in the isolated region. The more dense, first trench isolation layer in the second isolated trench also has the technical effect of being less vulnerable to etching during post-nanosheet processes, such as gate spacer and P-N junction formation, which ultimately reduces the potential for gate flop-over caused by undercutting of the oxide under the gate in the isolated region.

In an embodiment, a third height of the first trench isolation layer in the second isolation trench is equal to a first height of the first trench isolation layer in the plurality of first isolation trenches plus a second height of the second trench isolation layer in the plurality of first isolation trenches.

In an embodiment, the first trench isolation layer in the second isolation trench is substantially coplanar with a bottom surface of a nanosheet portion of the at least one second nanosheet fin structure.

According to another aspect of the present invention, a semiconductor device having improved nanosheet height control is provided. The semiconductor device includes a plurality of first nanosheet fin structures located in a dense array region of a substrate. The semiconductor device further includes a plurality of first isolation trenches between adjacent first nanosheet fin structures of the plurality of first nanosheet fin structures. The plurality of first isolation trenches include a first trench isolation layer, a protective layer formed on top of the first trench isolation layer, and a second trench isolation layer located above the protective liner. The second trench isolation layer is more dense than the first trench isolation layer. The protective liner separates the first trench isolation layer from the second trench isolation layer. Thus, illustrative embodiments provide for a technical effect of improved active height control during nanosheet processing, as well as during pre-nanosheet and post-nanosheet processes.

In an embodiment, a first height of the first trench isolation layer in the plurality of first isolation trenches is greater than a second height of the second trench isolation layer in the plurality of first isolation trenches.

In an embodiment, the first trench isolation layer is formed from a first oxide and the second trench isolation layer is formed from a second oxide.

In an embodiment, the first oxide used to form the first trench isolation layer and the second oxide used to form the second trench isolation layer are silicon dioxide.

In an embodiment, the first trench isolation layer in the plurality of first isolation trenches is below with a bottom surface of a nanosheet portion of the plurality of first nanosheet fin structures.

In an embodiment, the second trench isolation layer in the plurality of first isolation trenches is substantially coplanar with the bottom surface of the nanosheet portion of the plurality of first nanosheet fin structures.

In an embodiment, the first trench isolation layer is formed from flowable chemical vapor deposition of silicon dioxide, and the second trench isolation layer is formed from high density plasma chemical vapor deposition of silicon dioxide. This results in a technical effect of the second trench isolation layer being more dense then the first trench isolation layer.

In an embodiment, the semiconductor device further includes a second isolation trench separating the plurality of first fin structures in the dense array region of the substrate from at least one second nanosheet fin in an isolated region of the substrate. The plurality of first isolation trenches are narrower than the second isolation trench. The second isolation trench includes the first trench isolation layer, the protective layer formed on top of the first trench isolation layer, and the second trench isolation layer located above the protective liner. The more dense, second trench isolation layer in the second isolation trench has a technical effect of being less vulnerable to etching during pre-nanosheet processes, such as pre epitaxial cleaning of the silicon substrate (e.g., using a buffered oxide etch (BOE)) for subsequent nanosheet formation, which ultimately reduces the potential for gate flop-over caused by undercutting of the oxide under the gate in the isolated region. The more dense, first trench isolation layer in the second isolated trench also has the technical effect of being less vulnerable to etching during post-nanosheet processes, such as gate spacer and P-N junction formation, which ultimately reduces the potential for gate flop-over caused by undercutting of the oxide under the gate in the isolated region.

In an embodiment, the first trench isolation layer in the plurality of first isolation trenches and the first trench isolation layer in the second isolation trench have a same first height, and the second trench isolation layer in the plurality of first isolation trenches and the second trench isolation layer in the second isolation trench have a same second height.

In an embodiment, the first trench isolation layer in the second isolation trench is below with a bottom surface of a nanosheet portion of the plurality of first nanosheet fin structures.

In an embodiment, the second trench isolation layer in second isolation trench is substantially coplanar with the bottom surface of the nanosheet portion of the plurality of first nanosheet fin structures.

In an embodiment, the protective liner is further formed along respective sidewall portions the plurality of first isolation trenches and the second isolation trench extending between a top surface of the first trench isolation layer to a bottom surface of a nanosheet portion of the plurality of first nanosheet fin structures and the second nanosheet fin structure. This results in a technical effect of the second trench isolation layer in the dense array region and the isolated region being less vulnerable to etching during pre-nanosheet processes, such as pre epitaxial cleaning of the silicon substrate (e.g., using a buffered oxide etch (BOE)) for subsequent nanosheet formation, which ultimately reduces the potential for gate flop-over caused by undercutting the oxide under the gate. This also results in a technical effect of the second trench isolation layer in the dense array region and the isolated region being less vulnerable to etching during post-nanosheet processes, such as gate spacer and P-N junction formation, which ultimately reduces the potential for gate flop-over caused by undercutting of the oxide under the gate.

In an embodiment, the protective liner completely surrounds the first trench isolation layer formed in the plurality of first isolation trenches and the second isolation trench.

The aforementioned advantages, as well as any subsequently mentioned advantages are example advantages, and not all advantages are discussed. Furthermore, embodiments of the present disclosure can exist that contain all, some, or none of the aforementioned advantages and subsequently mentioned advantages while remaining within the spirit and scope of the present disclosure.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of semiconductor device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

As used herein, the term “deposition-loading effect” shall mean a change in the deposition rate of a material based on trench width. According to the term “deposition-loading effect” as used herein, a positive correlation exists between deposition rate and trench width. For example, the deposition rate of a material within a trench increases as the trench width increases. Similarly, the deposition rate of a material within a trench decreases as the trench width decreases.

As used herein, the term “dry etch-loading effect” shall mean a change in the dry etch rate of a material based on trench width. According to the term “dry etch-loading effect” as used herein, a positive correlation exists between dry etch rate and trench width. For example, the dry etch rate of a material within a trench increases as the trench width increases. Similarly, the dry etch rate of a material within a trench decreases as the trench width decreases.

As used herein, the term “wet etch-loading effect” shall mean a change in the wet etch rate of a material based on trench width. According to the term “wet etch-loading effect” as used herein, a negative correlation exists between wet etch rate and trench width. For example, the wet etch rate of a material within a trench decreases as the trench width increases. Similarly, the wet etch rate of a material within a trench increases as the trench width decreases.

Those skilled in the art understand that many different techniques may be used to add, remove, and/or alter various materials, and portions thereof, and that embodiments of the present invention may leverage combinations of such processes to produce the structures disclosed herein without deviating from the scope of the present invention.

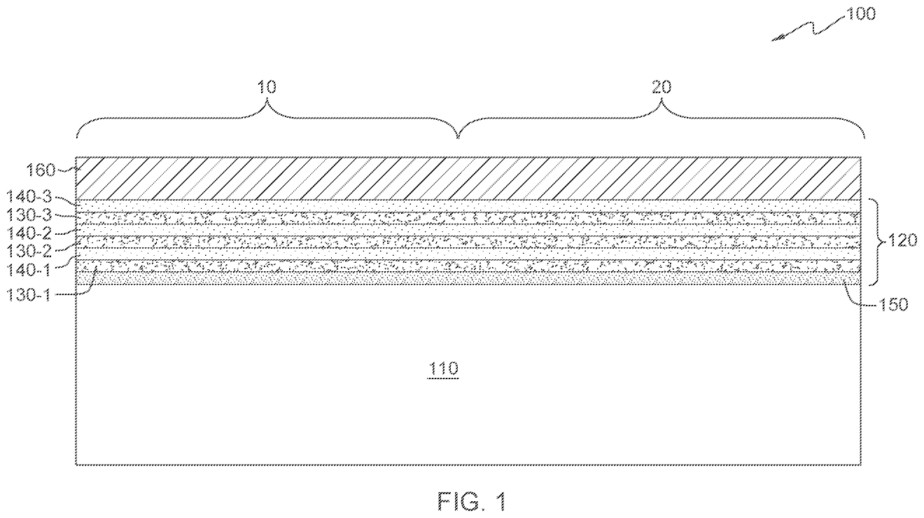

The present invention will now be described in detail with reference to the Figures. FIGS. 1-4 illustrate exemplary fabrication sequences that form a plurality of nanosheet fin structures in a dense array region of a semiconductor substrate and a single nanosheet fin structure in an isolated region of the semiconductor substrate. One having ordinary skill in the art will appreciate that there are many options available for the formation of the nanosheet fin structures described herein and that the following discussion does not limit embodiments to only the techniques described herein.

FIG. 1 illustrates a cross-sectional view of an initial semiconductor structure 100, in accordance with at least one embodiment of the present invention. Referring to FIG. 1, a nanosheet stack 120 is formed on a substrate 110, in which the substrate 110 incudes a region for a dense array of devices (i.e., dense array region 10), and a region for an isolated device (i.e., isolated region 20).

In some embodiments, and as depicted in FIG. 1, the substrate 110 is a bulk semiconductor wafer, such as a bulk silicon (Si), bulk germanium (Ge), bulk silicon germanium (SiGe) and/or bulk III-V semiconductor wafer. Alternatively, in other embodiments, the substrate 110 is a semiconductor-on-insulator (SOI) wafer. A SOI wafter includes a SOI layer separated from a substrate by a buried insulator. When the buried insulator is an oxide, it is referred to herein as a buried oxide or BOX. The SOI layer can include any suitable semiconductor, such as Si, Ge, SiGe, and/or a III-V semiconductor. The thickness of the substrate 110 may vary widely depending on the specific application. For example, the substrate 110 may have a thickness similar to that of a typical semiconductor wafer (e.g., 100-700 microns), or the substrate 110 may be thinned and mounted on another substrate.

In assembly of semiconductor structure 100, a nanosheet stack 120 is arranged above a sacrificial isolation layer 150. The nanosheet stack comprises an alternating arrangement of Si layers 140-1, 140-2, 140-3 and SiGe layers 130-1, 130-2, 130-3. Although three (3) Si layers and three (3) SiGe layers are shown, other numbers of Si layers and SiGe layers are contemplated. The nanosheet stack 120 may be further processed to define NFET region(s) and PFET region(s) of the semiconductor device.

The Si layers 140-1, 140-2, 140-3 and SiGe layers 130-1, 130-2, 130-3 may be epitaxially grown above the sacrificial isolation layer 150 (or above the BOX layer (not depicted)). As used herein, the term “epitaxially grown” means the growth of a semiconductor (crystalline) material on a deposition surface of another semiconductor (crystalline) material, in which the semiconductor material being grown (crystalline overlayer) has substantially the same crystalline characteristics as the semiconductor material of the deposition surface (seed material). In an epitaxial growth process, chemical reactants provided by source gases, as well as system parameters, are controlled to cause the depositing atoms to arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface. For example, an epitaxially grown semiconductor material deposited on a {100} orientated crystalline surface will take on a {100} orientation. In some embodiments, epitaxial growth processes are selective to forming on semiconductor surfaces, and generally do not deposit material on exposed surfaces such as silicon dioxide or silicon nitride surfaces.

The SiGe layers 130-1, 130-2, 130-3 may have any suitable atomic percentage of Ge. For convenience and ease of understanding, SiGe layers having a relatively lesser atomic percentage of Ge (such as the SiGe layers 130-1, 130-2, 130-3) will be referred as SiGe(x). In some embodiments, the SiGe(x) layers have a Ge concentration (x) from 5 atomic percent to 50atomic percent. In some embodiments, the SiGe(x) layers have a Ge concentration from 10 atomic percent to 40 atomic percent. In some embodiments, the SiGe(x) layers have a Ge concentration from 20 atomic percent to 30 atomic percent.

In some embodiments, the layers of the nanosheet stack 120 have a thickness less than or comparable to that of the sacrificial isolation layer 150. In some embodiments, the Si layers 140-1, 140-2, 140-3 have a thickness of 4 to 10 nm, and the SiGe(x) layers 130-1, 130-2, 130-3 have a thickness of 8 to 15 nm. In one non-limiting example, the sacrificial isolation layer 150 has a thickness of about 10 nm, the Si layers 140-1, 140-2, 140-3 have a thickness of about 6 nm, and the SiGe(x) layers 130-1, 130-2, 130-3 have a thickness of about 10 nm.

The sacrificial isolation layer 150 may be an SiGe layer with a relatively greater Ge concentration than the SiGe(x) layers 130-1, 130-2, 130-3. In some embodiments, the sacrificial isolation layer 150 may be a SiGe(x+25) layer having a Ge concentration that is at least 25 atomic percent greater than the SiGe(x) layers. In some embodiments, the nanosheet stack 120 may include one or more SiGe(x+25) layers in addition to the SiGe(x) layers. The greater Ge concentration in the SiGe(x+25) layers provides an etch selectivity greater than or equal to 30:1 relative to the lesser Ge concentration SiGe(x) layers. For example, the SiGe(x+25) layers may be selectively removed using HCl vapor etch chemistry.

In some embodiments in which the substrate 110 is formed from a bulk semiconductor material, the nanosheet stack 120 is formed by growing epitaxy layers above the substrate 110 as follows: a first SiGe layer having a high Ge concentration (e.g., greater than 50%) as a sacrificial isolation layer, and subsequent alternating layers of SiGe (e.g., 20-35% Ge) and Si above the sacrificial isolation layer.

In other embodiments in which the substrate 110 is formed from a SOI wafer, the nanosheet stack 120 may be formed as follows. The surface layer of the SOI wafer is thinned to have a thickness of approximately 5 to 10 nm. A layer of SiGe (30-60% Ge) is grown above the thinned surface layer. One example thickness of the SiGe layer is approximately 10 nm. An oxidation process is performed to intermix the Si of the surface layer with the SiGe layer to form a lower-concentration SiGe layer (20-40% Ge) with SiO₂ formed above. The SiO₂ may be removed using dilute hydrofluoric acid (DHF), and subsequent alternating layers of Si and SiGe (e.g., 20-35% Ge) may be grown above the lower-concentration SiGe layer.

After forming the nanosheet stack 120, a hard mask 160 is formed on top of the nanosheet stack 120. The hard mask 160, which is used for patterning the nanosheet stack 120, may be formed by depositing an inorganic hard mask material onto the top surface of the nanosheet stack 120. The hard mask 160 can be formed utilizing a deposition process including, but not limited to, CVD, PECVD, ALD, physical vapor deposition (PVD) or sputtering. In some embodiments, and as depicted, the hard mask 160 is formed from silicon nitride. However, other hard mask materials (e.g., titanium nitride, tantalum nitride, or any suitable inorganic metal-containing material) are contemplated.

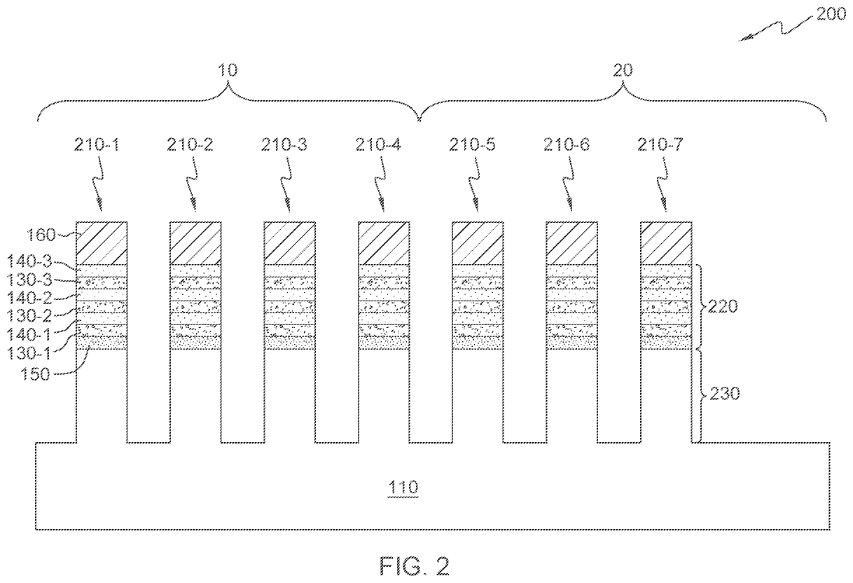

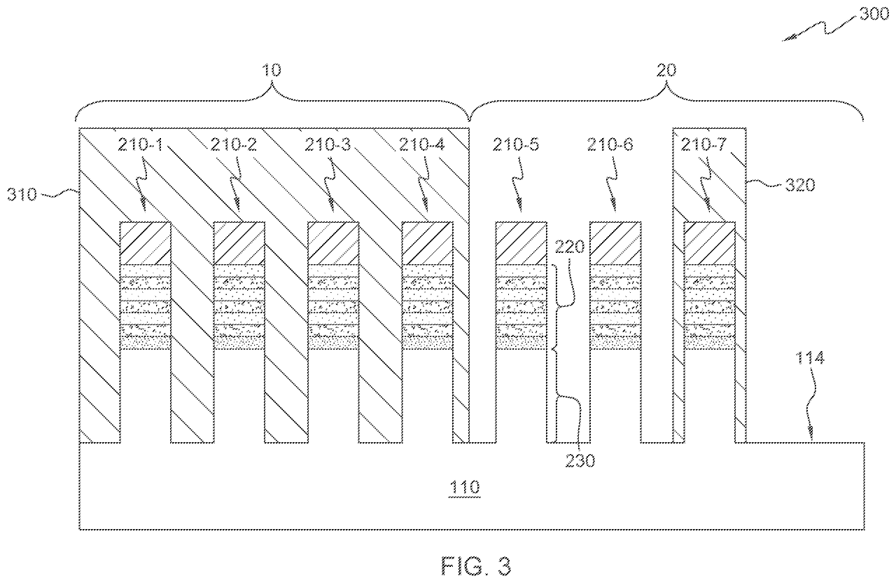

FIG. 2 illustrates a cross-sectional view of semiconductor structure 100 depicted in FIG. 1 after performing subsequent processing steps, generally designated 200, in accordance with at least one embodiment of the present invention. In assembly of semiconductor structure 200, and referring to the cross-sectional view of FIG. 2A, the nanosheet stack 120 and substrate 110 is patterned using the hard mask 160.

For example, patterning the nanosheet stack 120 and substrate 110 includes depositing a photoresist material (not depicted) onto the surface of the hard mask 160. The photoresist material can be applied by any suitable techniques, including, but not limited to, coating or spin-on techniques. A photomask (not depicted) patterned with shapes defining fin structures 210-1, 210-2, 210-3, 210-4, 210-5, 210-6, 210-7 to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the hard mask 160. One or more etch processes may be employed to selectively remove portions of the hard mask 160 to pattern the hard mask 160. After formation of the patterned hard mask 160, the photoresist material may be stripped from the patterned hard mask 160 by ashing or other suitable processes. The resulting structure may be subjected to a wet clean.

During patterning of the nanosheet stack 120 and the substrate 110 using the patterned hard mask 160, the physically exposed portions of the nanosheet stack 120 and substrate 110 are removed by an anisotropic etching process such as, for example, reactive ion etching (RIE), ion beam etching (IBE), chemical wet etching, or a combination of IBE and chemical wet etching. The etch removes the exposed portions of the nanosheet stack 120 and substrate 110 that are not protected by the patterned hard mask 160 to form fin structures 210-1, 210-2, 210-3, 210-4, 210-5, 210-6, 210-7 in the dense array region 10 and isolated region 20 of the substrate 110.

As depicted, the resulting nanosheet fin structures 210-1, 210-2, 210-3, 210-4, 210-5, 210-6, 210-7 are formed having a single, uniform pitch. The “pitch” is the center to center distance between adjacent nanosheet fin structures. Each of the nanosheet fin structures 210-1-210-7 include a nanosheet portion 220 formed from the sacrificial isolation layer 150 and the nanosheet stack 120, and a fin portion 230 formed from the substrate 110. Each nanosheet portion 220 of the nanosheet fin structures 210-1-210-7 has a uniform height H1, and extends from the surface 112 of the substrate 110 that is in direct contact with the sacrificial isolation layer 150 to the top surface 122 of nanosheet stack 120. Each fin portion 230 of the nanosheet fin structures 210-1-210-7 has a uniform height H2, and extends from the surface 114 of the substrate 110 to the surface 112 of the substrate 110 that is in direct contact with the sacrificial isolation layer 150.

FIG. 3 illustrates a cross-sectional view of semiconductor structure 200 depicted in FIG. 2 after performing subsequent processing steps, generally designated 300, in accordance with at least one embodiment of the present invention. In assembly of semiconductor structure 300, and referring to the cross-sectional view of FIG. 3, the semiconductor structure 200 of FIG. 2 is further patterned to define the dense array region 10 and the isolated region 20. In some embodiments, and as depicted, patterning the semiconductor structure 200 of FIG. 2 includes forming block masks 310, 320. The block masks 310, 320 define which nanosheet fin structures are to be maintained in the dense array region 10 and isolated region 20, respectively.

The block masks 310, 320 may be composed of an inorganic hard mask material (e.g., silicon nitride, titanium nitride, tantalum nitride, or any suitable inorganic metal-containing material) or an organic soft mask material (e.g., carbon, hydrogen, oxygen, and optionally nitrogen, fluorine, and silicon). The block masks 320, 330 may be formed using the same processes and materials as described above with reference to patterning the hard mask 160 of FIG. 2. Block mask 310 protects nanosheet fin structures 210-1, 210-2, 210-3, 210-4 in the dense array region 10, while block mask 320 protects a single nanosheet fin structure 210-7 in the isolated region 20. The remaining nanosheet fin structures 210-5, 210-6 remain exposed.

During patterning of the semiconductor structure 200 of FIG. 2 using the block masks 310, 320, the physically exposed nanosheet portions 220 and the underlying fin portions 230 of nanosheet fin structures 210-5, 210-6 not protected by the block masks 320, 330 are removed by an anisotropic etching process (e.g., reactive ion etching (RIE), ion beam etching (IBE), chemical wet etching, or a combination of IBE and chemical wet etching), while nanosheet fin structures 210-1, 210-2, 210-3, 210-4, and 210-7 protected by the block masks 310, 320 are preserved. The extent to which nanosheet fins 210-5, 210-6 are recessed can be controlled by a timed etching process, such that etching terminates upon reaching the surface 114 of the substrate 110.

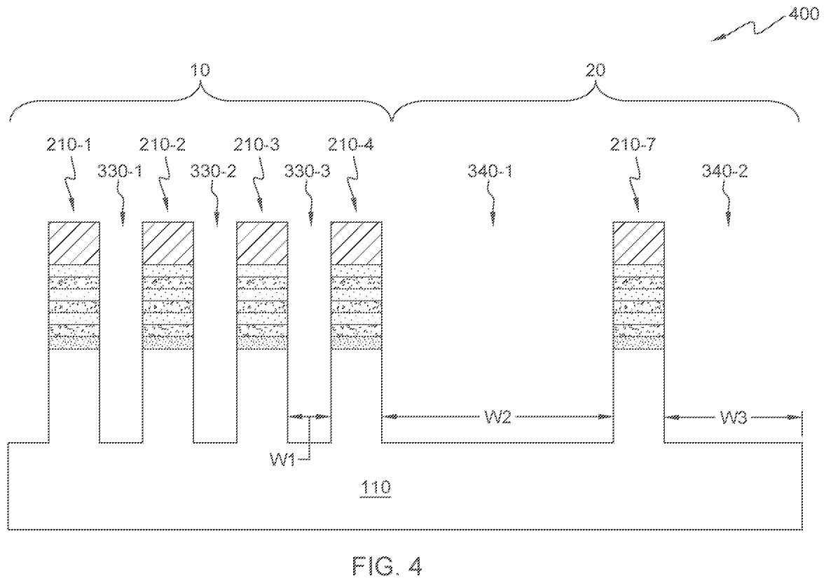

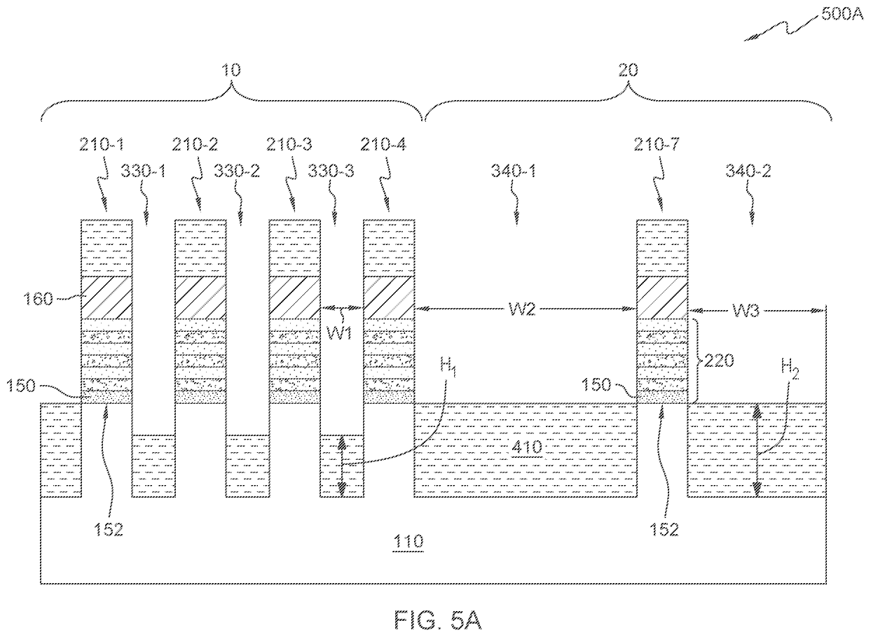

FIG. 4 illustrates a cross-sectional view of semiconductor structure 300 depicted in Figure after performing subsequent processing steps, generally designated 400, in accordance with at least one embodiment of the present invention. In assembly of semiconductor structure 400, and referring to the cross-sectional view of FIG. 4, the block masks 310, 320 have been removed using one or more mask removal processes (e.g., hot phosphoric acid) as known by one of ordinary skill in the art and, as such, a more detailed description of such processes is not presented herein.

After the removal of the block masks 310, 320, first nanosheet fin structures (i.e., nanosheet fin structures 210-1. 210-2, 210-3, 210-4) are located in the dense array region 10, while second nanosheet fin structure (i.e., nanosheet fin structure 210-7) is located in the isolated region. The resulting semicondutor structure 400 further includes isolation trenches 330-1. 330-2, 330-3 (collectively referred to herein as a plurality of first isolation trenches) formed between adjacent nanosheet fin structures 210-1, 210-2, 210-3, 210-4 in the dense array region 10, and isolation trenches 340-1, 340-2 (collectively referred to herein as second isolation trenches) formed adjacent to the nanosheet fin structure 210-7 in the isolated region 20. As depicted, the trench width W1 of isolation trenches 330-1, 330-2, 330-3 in the dense array region 10 is significantly narrower than the trench widths W2. W3 of isolation trenches 340-1, 340-2 of the isolated region 20.

FIGS. 5A-8A depict various operations of a first fabrication sequence beginning with the semiconductor structure 400 of FIG. 4, in accordance with at least one embodiment of the present invention. FIG. 5A illustrates a cross-sectional view of semiconductor structure 400 depicted in FIG. 4 after performing subsequent processing steps, generally designated 500A, in accordance with at least one embodiment of the present invention. In assembly of semiconductor structure 500A, and referring to the cross-sectional view of FIG. 5A, a first trench isolation material is simultaneously deposited within isolation trenches 330-1, 330-2, 330-3 of the dense array region 10 and isolation trenches 340-1, 340-2 of the isolated region 20 to a form a first trench isolation layer 410.

In some embodiments, and as depicted, the first trench isolation layer 410 is formed by performing high density plasma chemical vapor deposition (HDPCVD) of an oxide material, such as silicon dioxide (SiO₂). HDPCVD is a special form of plasma enhanced chemical vapor deposition (PECVD) that uses an inductively coupled plasms (ICP) source that provides a higher plasma density than a standard parallel-place PECVD system. High plasma density using ICP makes it possible to form more dense films at even lower temperatures (e.g., under 150° C.). However, in other embodiments, the first trench isolation layer 410 may be formed using alternative deposition techniques, such as chemical vapor deposition (CVD), plasma enhanced chemical vapor deposition (PECVD), atomic layer deposition (ALD), physical vapor deposition (PVD), sputtering, chemical solution deposition, or any other suitable deposition techniques.

In some embodiments, and as depicted in FIG. 5A, the first trench isolation layer 410 is composed of a dielectric. In an embodiment, the first trench isolation layer 410 is composed of an oxide, such as silicon dioxide (SiO₂). However, the first trench isolation layer 410 may be composed of other inorganic dielectric materials or an organic dielectric material. Examples of suitable dielectric materials that may be employed as the first trench isolation layer 410 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

One or more anisotropic etching processes, such as, for example, reactive ion etching (RIE), ion beam etching (IBE), chemical wet etching, or a combination of IBE and chemical wet etching may be subsequently employed to remove any of the first trench isolation material formed onto the sidewalls of the hard mask 160 and the nanosheet fin structures 210-1, 210-2, 210-3, 210-4, 210-above the bottom surface 152 of the sacrificial isolation layer 150.

Deposition of the first trench isolation layer may terminate when the first trench isolation layer 410 is substantially coplanar with a bottom surface 152 of the sacrificial isolation layer 150 of the nanosheet portion 220 of the nanosheet fin structure 210-7 in the isolated region 20. Due to a deposition-loading effect caused by a difference in the trench width W1 of the isolation trenches 330-1, 330-2, 330-3 330 formed between adjacent nanosheet fin structures 210-1, 210-2, 210-3, 210-4 in the dense array region 10, and the trench widths W2, W3 of the isolation trenches 340-1, 340-2 formed adjacent to the nanosheet fin structure 210-7 in the isolated region 20, the deposition rate of the first trench isolation material is higher in the isolation trenches 340-1, 340-2 in the isolated region 20 than in the isolation trenches 330-1, 330-2, 330-3 in the dense array region 10. This results in the height H1 of the first trench isolation layer 410 in the isolated region 20 being greater than the height H2 of the first trench isolation layer 410 in the dense array region 10. By advantageously using the deposition-loading effect, the reveal height of the nanosheet fin structure 210-7 in the isolated region 20 is completed during the deposition of the first trench isolation material, and without the need for any subsequent etching processes.

FIG. 6A illustrates a cross-sectional view of semiconductor structure 500A depicted in FIG. 5A after performing subsequent processing steps, generally designated 600A, in accordance with at least one embodiment of the present invention. In assembly of semiconductor structure 600A, and referring to the cross-sectional view of FIG. 6A, a protective liner 510 is formed along the exposed surfaces of the semicondutor structure 500A of FIG. 5A, followed by the formation of a second trench isolation layer 520 on top of the protective liner 510.

The protective liner 510 may be formed by conformally depositing a protective liner material onto the exposed surfaces semiconductor structure 400A. Is some embodiments, and as depicted, the protective liner 510 is composed of silicon nitride (SiN). However, in other embodiments, the protective liner 510 may be composed of one or more thin layers of a metal liner material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN) manganese (Mn), manganese nitride (MnN) or other barrier materials (or combinations of barrier materials) such as RuTaN, Ta/TaN, CoWP, NiMoP, or NiMoB which are suitable for the given application. A conformal layer of a protective liner material may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating. The thickness of the protective layer 510 may vary depending on the deposition process used, as well as the material employed. In some embodiments, the protective liner 510 may have a thickness from 2 nm to 50 nm. However, other thicknesses that are less than 2 nm, or greater than 50 nm can also be employed in embodiments of the present invention.

Following the formation of the protective liner 510, the second trench isolation layer 520 is formed on top of the protective liner 520. In some embodiments, and as depicted in FIG. 6A, the second trench isolation layer 520 is composed of an oxide, such as silicon dioxide (SiO2), and is formed on top of the protective liner 510 using, for example, flowable chemical vapor deposition (FCVD). However, in other embodiments, the second trench isolation layer 520 may be composed of any of the dielectric materials as discussed above with reference to the first trench isolation layer 410 of FIG. 4A. Similarly, in other embodiments, the second trench isolation layer 520 may be formed using other deposition processes, such as physical vapor deposition (PVD), atomic layer deposition (ALD), chemical vapor deposition (CVD), plasma enhanced CVD (PECVD), or any other suitable deposition techniques).

In some embodiments, the semiconductor structure 600A is further subjected to an annealing process (e.g., steam anneal, furnace anneal, rapid thermal anneal, flash anneal, or laser anneal) for densification of the second trench isolation layer 520. It should be appreciated that the protective liner 510 prevents any oxidation of the nanosheet fin structures 210-1, 210-2, 210-3, 210-4, 210-7 during the annealing process.

In some embodiments, and as depicted, the first trench isolation layer 410 and the second trench isolation layer 520 are composed of the same trench isolation materials, but have different densities. For example, the first trench isolation layer 410 is formed by high density plasma chemical vapor deposition (HDPCVD) of silicon dioxide (SiO₂), and the second trench isolation layer 520 is formed by flowable chemical vapor deposition (FCVD) of silicon dioxide (SiO₂), which will result in the first trench isolation layer 410 being more dense than the second trench isolation layer 520.

FIG. 7A illustrates a cross-sectional view of semiconductor structure 600A depicted in FIG. 6A after performing subsequent processing steps, generally designated 700A, in accordance with at least one embodiment of the present invention. In assembly of semiconductor structure 700A, and referring to the cross-sectional view of FIG. 7A, a chemical planarization process is performed, followed by recessing of the second trench isolation layer 520 using a single etching process.

The planarization process, such as, for example, chemical mechanical planarization or polishing (CMP) and/or grinding, may be performed to remove any of the protective liner 510 and second trench isolation layer 520 present above the top surface 162. The planarization stops when the second trench isolation layer 520 is substantially coplanar with top surface 162 of the hard mask 160.

In a following process step, a single etching process (e.g., a dry etch that is selective to the second trench isolation layer 520 over the protective liner 510) is performed. Recessing of the second trench isolation layer 520 may terminate when the second trench isolation layer 520 is substantially coplanar with the bottom surface 152 of the sacrificial isolation layer 150 of the nanosheet portion 220 of the nanosheet fin structures 210-2, 210-2, 210-3, 210-4 in the dense array region 10. Due to a dry etch-loading effect caused by a difference in the trench width W1 of the isolation trenches 330-1, 330-2, 330-3 330 formed between adjacent nanosheet fin structures 210-1. 210-2, 210-3, 210-4 in the dense array region 10, and the trench widths W2, W3 of the isolation trenches 340-1. 340-2 formed adjacent to the nanosheet fin structure 210-7 in the isolated region 20, the etch rate of the second trench isolation layer 520 is higher in the isolated region 20 than in the dense array region 10. This results in a portion of the second trench isolation layer 520 left remaining in the dense array region 10 after all of the second trench isolation layer 520 has been removed from the isolated region 20.

Furthermore, by using an etchant that is selective to the second trench isolation layer 520 over the protective liner 510, the second trench isolation layer 520 can continue to be recessed in the dense array region 10 without concern of altering the reveal height of the nanosheet fin structure 210-7 in the isolated region 10, even after all of the second trench isolation layer 520 has been removed from the isolated region 10. Accordingly, by advantageously using the dry etch-loading effect, recessing of the second isolation trench layer 520 can be targeted to the dense array region 10 to achieve the same reveal height for the nanosheet fin structures 210-1, 210-2, 210-3, 210-4 in the dense array region 10 as the reveal height of the nanosheet fin structure 210-7 in the isolated region 20.

FIG. 8A illustrates a cross-sectional view of semiconductor structure 700A depicted in FIG. 7A after performing subsequent processing steps, generally designated 800A, in accordance with at least one embodiment of the present invention. In assembly of semiconductor structure 800A, and referring to the cross-sectional view of FIG. 8A, the hard mask 160 and portions of the protective liner 510 are removed using an etchant that is selective to the material(s) of the protective liner 510 and the patterned hard mask 160.

For example, if the protective liner 510 and the patterned hard mask layer 160 are composed of a nitride, such as silicon nitride (SiN), and the first and second trench isolation layers 410, 520 are composed of an oxide, such as silicon dioxide (SiO₂), then a wet etchant such as hot phosphoric acid may be used to remove the nitride material of the first and second trench isolation layers 410, 520 and the hard mask 160 selectively to the oxide material of the first and second trench isolation layers 410, 520. Similarly, since the patterned nanosheet stack 120 is not composed of a nitride, the hot phosphoric acid also will not etch the alternating layers of SiGe and Si of the patterned nanosheet stack 120.

As depicted, the protective liner 510 is completely removed from the isolated region 20, such that only the first trench isolation layer 410 remains in the trench isolation areas 340-1, 340-2 adjacent to the nanosheet fin structure 210-7 in the isolated region 20. It should be appreciated that since only the first trench isolation layer 410 (which is more dense/of higher quality than the second trench isolation layer 520) exists with the isolation trenches 340-1, 340-2 in the isolated region 20, the isolated nanosheet fin structure 210-7 is less vulnerable to gate flop-over caused by undercutting of the first trench isolation layer 410 during downstream processes, such as gate spacer and P-N junction formation.

As further depicted, a “U-shaped” portion of the protective liner 510 remains embedded within the isolation trenches 330-1, 330-2, 330-3 in the dense array region 10. In particular, the “U-shaped” portion of the protective liner is arranged on top of the first trench isolation layer 410 and along the sidewall portions of the fin structures 230 of the nanosheet fin structures 210-1, 210-2, 210-3, 210-4 extending between the top surface of the first trench isolation layer 410 and the bottom surface 152 of the sacrificial isolation layer 150. The denser, first trench isolation layer 410 is located below the protective liner 510, while the less dense, second trench isolation layer 520 is located above the protective liner 510.

Referring now to FIGS. 5B-8B, FIGS. 5B-8B depict various operations of a second fabrication sequence beginning with the semiconductor structure 400 of FIG. 4, in accordance with at least one embodiment of the present invention. FIG. 5B illustrates a cross-sectional view of semiconductor structure 400 depicted in FIG. 4 after performing subsequent processing steps, generally designated 500B, in accordance with at least one embodiment of the present invention. In assembly of semiconductor structure 500B, and referring to the cross-sectional view of FIG. 5B, a protective liner 450 is formed along the exposed surfaces of the semicondutor structure 400, a first trench isolation layer 460 is formed on top of the protective liner 450, followed by a planarization process.

In some embodiments, the protective liner 450 may be formed by conformally depositing a protective liner material, such as silicon nitride (SiN), onto the exposed surfaces semiconductor structure 400A. However, the protective liner 450 may also be formed using any of the materials and processes as discussed above with reference to the protective liner 510 of FIG. 6A.

Following the formation of the protective liner 450, a first trench isolation layer 460 is formed on top of the protective liner 450. In some embodiments, and as depicted in FIG. 4B, the first trench isolation layer 460 is composed of an oxide, such as silicon dioxide (SiO2), and is formed on top of the protective liner 450 using, for example, flowable chemical vapor deposition (FCVD). However, in other embodiments, the first trench isolation layer 460 may be formed using any of the materials and processes as discussed above with reference to the second trench isolation layer 520 of FIG. 5A.

In some embodiments, the semiconductor structure 500B is further subjected to an annealing process (e.g., steam anneal, furnace anneal, rapid thermal anneal, flash anneal, or laser anneal) for densification of the first trench isolation layer 460. It should be appreciated that the protective liner 450 prevents any oxidation of the nanosheet fin structures 210-1, 210-2, 210-3, 210-4, 210-7 during the annealing process. A planarization process such as, for example, chemical mechanical planarization or polishing (CMP) and/or grinding, may subsequently be performed to remove any of the first trench isolation layer 460 located above the top surface 452 of the protective liner 450. The planarization stops when the first trench isolation layer 460 is substantially coplanar with the top surface 452 of the protective liner 450.

FIG. 6B illustrates a cross-sectional view of semiconductor structure 500B depicted in FIG. 5B after performing subsequent processing steps, generally designated 600B, in accordance with at least one embodiment of the present invention. In assembly of semiconductor structure 600B, and referring to the cross-sectional view of FIG. 6B, the first trench isolation layer 460 is partially recessed using a multistep etching process.

The multistep etching process, which may include a wet etching process, followed by a dry etching process (or vice versa), is required to counterbalance one loading effect (e.g., a dry etch-loading effect) with another loading effect (e.g., a wet etch-loading effect) in order to obtain a uniform height H4 of the first trench isolation layer within isolation trenches 330-1, 330-2, 330-330 in the dense array region 10, and isolation trenches 340-1, 340-2 in the isolated region 20. For example, the use of a wet etching process will result in a wet-loading effect, in which the etch rate of the first trench isolation layer 460 a trench width W3 that is significantly narrower than. Conversely, the use of a dry etching process will result in the etch rate of the first trench isolation layer 460 being higher in the isolated region 20 than in the dese array region 10. Thus, in order to obtain a uniform height for the first trench isolation layer 460 in the dense array and isolated regions 10, 20, a combination of wet etching and drying etching may be employed.

Recessing of the first trench isolation layer 460 may terminate when the top surface 462 of first trench isolation layer 460 is below the bottom surface 152 of the sacrificial isolation layer 150 of the nanosheet portion 220 of the nanosheet fin structures 210-2, 210-2, 210-3, 210-4, 210-7. In various embodiments, the height H4 of the first trench isolation layer 460 may be higher than or lower than as depicted, so long as the top surface 462 of the first trench isolation layer is below the top surface 152 of the sacrificial isolation layer 150.

FIG. 7B illustrates a cross-sectional view of semiconductor structure 600B depicted in FIG. 6B after performing subsequent processing steps, generally designated 700B, in accordance with at least one embodiment of the present invention. In assembly of semiconductor structure 700B, and referring to the cross-sectional view of FIG. 7B, a protective liner material is deposited to form a second protective liner 650, followed by a second trench isolation layer 660 formed on top of the second protective liner 650.

In some embodiments, the second protective liner 650 may be formed by directionally depositing a protective liner material, such as silicon nitride (SiN), onto the top surface 462 of the first trench isolation layer 460. As depicted, the directional deposition may also result in the formation of the second protective liner 650 on top of the first protective liner 450 located above the hard mask 160. However, in other embodiments, the second protective liner 650 may also be formed using any of the materials and processes as discussed above with reference to forming the first protective liner 510 of FIG. 56.

Following the formation of the second protective liner 650, a second trench isolation layer 660 is formed on top of the second protective liner 650. In some embodiments, and as depicted in FIG. 7B, the second trench isolation layer 660 is formed on top of the second protective liner 650 by performing high density plasma chemical vapor deposition (HDPCVD) of an oxide material, such as silicon dioxide (SiO₂). However, in other embodiments, the second trench isolation layer 660 may be formed using any of the materials and processes as described above with reference to forming the first trench isolation layer 410 of FIG. 5A.

FIG. 8B illustrates a cross-sectional view of semiconductor structure 700B depicted in FIG. 7B after performing subsequent processing steps, generally designated 800B, in accordance with at least one embodiment of the present invention. In assembly of semiconductor structure 800B, and referring to the cross-sectional view of FIG. 8B, the hard mask 160 and portions of the first protective liner 450 and the second protective liner 650 located above the top surface 662 of the second trench isolation layer 660 are removed using one or more etching processes.

In some embodiments, the one or more etching processes includes using an etchant that is selective to the material(s) of the first protective liner 450, the second protective liner 650, and the patterned hard mask 160. For example, if the first protective liner 450, the second protective liner 650, and the patterned hard mask layer 160 are all composed of a nitride, such as silicon nitride (SiN), and the second trench isolation layer is composed of an oxide, such as silicon dioxide (SiO₂), then a wet etchant such as hot phosphoric acid may be used to remove the nitride material of the first and second protective liners 450, 650 and the hard mask 160 selectively to the oxide material of the second trench isolation layer 660. Similarly, since the patterned nanosheet stack 120 is not composed of a nitride, the hot phosphoric acid also will also etch the first and second protective liners 450, 650 and the hard mask 160 selectively to the alternating layers of SiGe and Si of the patterned nanosheet stack 120.

As depicted, a combination of the first protective liner 450 and the second protective liner 650 completely surround the first trench isolation layer 460 in both isolation trenches 350-1, 350-2, 350 of the dense array region 10 and isolation trenches 360-1, 360-2 of the isolated region, while the second trench isolation layer 660 is located on top of the second protective liner 650. As further depicted, a portion of the first protective liner 450 is also located along the sidewall portions of the fin structures 230 of the nanosheet fin structures 210-1, 210-2, 210-3, 210-4, 210-7 extending between the top surface of the first trench isolation layer 460 and the bottom surface 152 of the sacrificial isolation layer 150. The less dense, first trench isolation layer 460 is located below the protective liner 650, while the denser, second trench isolation layer 660 is located above the protective liner 650.

It should be appreciated that since the second trench isolation layer 660 (which is more dense/of higher quality than the second trench isolation layer 520) exists at the top of the isolation trenches 350-1, 350-2, 350-3, 360-1, 360-2, the nanosheet fin structures in both the dense array region 10 and isolated region are less vulnerable to gate flop-over caused by undercutting of the second trench isolation layer 660 during post nanosheet processing, such as gate spacer and P-N junction formation. It should further be appreciated that the protective liner formed between the first and second trench isolation layers has the technical effect of reducing and/or eliminating any gate flop-over caused by the potential removal of the second trench isolation layer 660 during additional post nanosheet processes, such as performing a buffered oxide etch (BOE), also known as HF or BHF, for pre epitaxial cleaning of the silicon substrate for subsequent nanosheet formation.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

What is claimed is:

1. A semiconductor device, comprising:
a plurality of first nanosheet fin structures located in a dense array region of a substrate; and
a plurality of first isolation trenches between adjacent first nanosheet fin structures of the plurality of first nanosheet fin structures, wherein the plurality of first isolation trenches include:
a first trench isolation layer;
a protective liner formed on top of the first trench isolation layer; and
a second trench isolation layer located above the protective liner, wherein:
the protective liner separates the first trench isolation layer from the second trench isolation layer; and
the first trench isolation layer is more dense than the second trench isolation layer.

2. The semiconductor device of claim 1, wherein a first height of the first trench isolation layer in the plurality of first isolation trenches is greater than a second height of the second trench isolation layer in the plurality of first isolation trenches.

3. The semiconductor device of claim 1, wherein the first trench isolation layer is formed from a first oxide and the second trench isolation layer is formed from a second oxide.

4. The semiconductor device of claim 3, wherein the first oxide used to form the first trench isolation layer and the second oxide used to form the second trench isolation layer are silicon dioxide.

5. The semiconductor device of claim 1, wherein the first trench isolation layer is formed from high density plasma chemical vapor deposition of silicon dioxide, and the second trench isolation layer is formed from flowable chemical vapor deposition of silicon dioxide.

6. The semiconductor device of claim 1, wherein the second trench isolation layer in the plurality of first isolation trenches is substantially coplanar with a bottom surface of a nanosheet portion of the plurality of first nanosheet fin structures.

7. The semiconductor device of claim 1, wherein the protective liner is further formed along respective sidewall portions the plurality of first isolation trenches extending between a top surface of the first trench isolation layer to a bottom surface of a nanosheet portion of the plurality of first nanosheet fin structures.

8. The semiconductor device of claim 1, further comprising:
a second isolation trench separating the plurality of first nanosheet fin structures in the dense array region of the substrate from at least one second nanosheet fin structure in an isolated region of the substrate, wherein:
the plurality of first isolation trenches are narrower than the second isolation trench; and
the second isolation trench includes the first trench isolation layer.

9. The semiconductor device of claim 8, wherein a third height of the first trench isolation layer in the second isolation trench is equal to a first height of the first trench isolation layer in the plurality of first isolation trenches plus a second height of the second trench isolation layer in the plurality of first isolation trenches.

10. The semiconductor device of claim 8, wherein the first trench isolation layer in the second isolation trench is substantially coplanar with a bottom surface of a nanosheet portion of the at least one second nanosheet fin structure.

11. A semiconductor device, comprising:
a plurality of first nanosheet fin structures located in a dense array region of a substrate; and
a plurality of first isolation trenches between adjacent first nanosheet fin structures of the plurality of first nanosheet fin structures, wherein the plurality of first isolation trenches include:
a first trench isolation layer;
a protective liner formed on top of the first trench isolation layer; and
a second trench isolation layer located above the protective liner, wherein:
the protective liner separates the first trench isolation layer from the second trench isolation layer; and
the second trench isolation layer is more dense than the first trench isolation layer.

12. The semiconductor device of claim 11, wherein a first height of the first trench isolation layer in the plurality of first isolation trenches is greater than a second height of the second trench isolation layer in the plurality of first isolation trenches.

13. The semiconductor device of claim 11, wherein the first trench isolation layer is formed from a first oxide and the second trench isolation layer is formed from a second oxide.

14. The semiconductor device of claim 13, wherein the first oxide used to form the first trench isolation layer and the second oxide used to form the second trench isolation layer are silicon dioxide.

15. The semiconductor device of 11, wherein the first trench isolation layer in the plurality of first isolation trenches is below with a bottom surface of a nanosheet portion of the plurality of first nanosheet fin structures.

16. The semiconductor device of claim 15, wherein the second trench isolation layer in the plurality of first isolation trenches is substantially coplanar with the bottom surface of the nanosheet portion of the plurality of first nanosheet fin structures.

17. The semiconductor device of claim 11, further comprising:
a second isolation trench separating the plurality of first nanosheet fin structures in the dense array region of the substrate from at least one second nanosheet fin structure in an isolated region of the substrate, wherein:
the plurality of first isolation trenches are narrower than the second isolation trench; and
the second isolation trench includes the first trench isolation layer and the second trench isolation layer.

18. The semiconductor device of claim 17, wherein the first trench isolation layer in the plurality of first isolation trenches and the first trench isolation layer in the second isolation trench have a same first height, and the second trench isolation layer in the plurality of first isolation trenches and the second trench isolation layer in the second isolation trench have a same second height.

19. The semiconductor device of claim 17, wherein the first trench isolation layer in the second isolation trench is below with a bottom surface of a nanosheet portion of the at least one second nanosheet fin structure.

20. The semiconductor device of claim 19, the second trench isolation layer in the second isolation trench is substantially coplanar with the bottom surface of the nanosheet portion of the plurality of the at least one second nanosheet fin structure.

21. The semiconductor device of claim 17, wherein the protective liner is further formed along respective sidewall portions the plurality of first isolation trenches and the second isolation trench extending between a top surface of the first trench isolation layer to a bottom surface of a nanosheet portion of the plurality of first nanosheet fin structures and the second nanosheet fin structure.

22. The semiconductor device of claim 17, wherein the protective liner completely surrounds the first trench isolation layer formed in the plurality of first isolation trenches and the second isolation trench.

23. A method of forming a semiconductor device, comprising:
arranging a nanosheet stack on top of a substrate;
patterning the nanosheet stack and the substrate to form a plurality of first nanosheet fin structures in a dense array region of the substrate and at least one second nanosheet fin structure in an isolated region of the substrate, wherein patterning the nanosheet stack and the substrate further results in the formation of a first trench isolation region between adjacent first nanosheet fin structures of the plurality of nanosheet fin structures, and a second trench isolation region separating the dense array region of the substrate from the isolated region of the substrate;
simultaneously depositing a first oxide material within the first trench isolation region and the second trench isolation region to form a first trench isolation layer, wherein the first trench isolation layer is higher in the second trench isolation region than in the first trench isolation region due to a loading effect caused by a difference in trench width between the first trench isolation region and the second trench isolation region;
stopping simultaneously depositing the first oxide in the first trench isolation region and the second trench isolation region when a first height of the first trench isolation layer in the second trench isolation region is substantially coplanar with a bottom surface of a nanosheet portion of the at least one second nanosheet fin structure, at which point a second height of the first trench isolation layer in the first trench isolation region will be below a bottom surface of the nanosheet portion of the plurality of first nanosheet fin structures;
conformally depositing a protective liner material to form a protective liner over the first trench isolation layer, the plurality of first nanosheet fin structures in the dense array region, and the at least one second nanosheet fin structure in the isolated region;
simultaneously depositing a second oxide material within the first trench isolation region and the second trench isolation region to form a second trench isolation layer, wherein the second trench isolation layer is less dense than the first trench isolation layer;
simultaneously performing a dry etching process in the first trench isolation region and the second trench isolation region that is selective to the second trench isolation layer over the protective liner, wherein an etch rate of the second trench isolation layer is faster in the second trench isolation region than in the first trench isolation region due to a loading effect caused by the difference in trench width between the first trench isolation region and the second trench isolation region;
stopping simultaneously performing the dry etching process in the first trench isolation region and the second trench isolation region when a third height of the second trench isolation layer in the first trench isolation region is substantially coplanar with the bottom surface of the nanosheet stack portion of the plurality of first nanosheet fin structures, at which point all of the second trench isolation layer will have been removed from the second trench isolation region.

24. A method of forming a semiconductor device, comprising:
arranging a nanosheet stack on top of a substrate;
patterning the nanosheet stack and the substrate to form a plurality of first nanosheet fin structures in a dense array region of the substrate and at least one second nanosheet fin structure in an isolated region of the substrate, wherein patterning the nanosheet stack and the substrate further results in the formation of a first trench isolation region between adjacent first nanosheet fin structures of the plurality of nanosheet fin structures, and a second trench isolation region separating the dense array region of the substrate from the isolated region of the substrate;
conformally depositing a protective liner material to form a first protective liner over the plurality of first nanosheet fin structures in the dense array region of the substrate and the at least one second nanosheet fin structure in the isolated region of the substrate;
simultaneously depositing a first oxide material within the first trench isolation region and the second trench isolation region to form a first trench isolation layer;
simultaneously performing one or more etching processes in the first trench isolation region and the second trench isolation region to recess the first trench isolation layer below a nanosheet portion of the plurality of first nanosheet fin structures, and the at least one second nanosheet fin structure;
directionally depositing the protective liner material to form a second protective liner over the first trench isolation layer;
simultaneously depositing a second oxide material within the first trench isolation region and the second trench isolation region to form a second trench isolation layer, wherein the second trench isolation layer is denser than the first trench isolation layer;
simultaneously performing an etching process in the first trench isolation region and the second trench isolation region to recess the second trench isolation layer until the second trench isolation layer is substantially coplanar with a bottom surface of a nanosheet stack portion of the plurality of first nanosheet fin structures and the at least one second nanosheet fin structure.
